(19) United States
(12) Patent Application Publication
(10) Pub. No.: US 2025/0331103 A1
(43) Pub. Date: Oct. 23, 2025

(54) CIRCUIT BOARD AND ELECTRONIC DEVICE

(71) Applicant: RUIJIE NETWORKS CO., LTD., Fuzhou (CN)

(72) Inventors: Jian YANG, Fuzhou (CN); Xusheng CHENG, Fuzhou (CN); Anbing SUN, Fuzhou (CN)

(73) Assignee: RUIJIE NETWORKS CO., LTD., Fuzhou (CN)

(21) Appl. No.: 19/259,211

(22) Filed: Jul. 3, 2025

Related U.S. Application Data
(63) Continuation of application No. PCT/CN2024/102144, filed on Jun. 27, 2024.

(30) Foreign Application Priority Data
Jul. 7, 2023 (CN) 202310834211.4

(51) Int. Cl. H05K 1/02; H05K 1/11

(52) U.S. Cl. CPC H05K 1/0296; H05K 1/115; H05K 2201/10303

(57) ABSTRACT

A circuit board and an electronic device. The circuit board includes a board body, where a surface of the board body has a chip installation region and a signal connector installation region arranged along a first direction; an end of the chip installation region away from the signal connector installation region has a first signal pin region, and in the chip installation region, the first signal pin region is the farthest from the signal connector installation region; and pins of the first signal pin region are in signal connection with corresponding pins of the signal connector installation region through a first signal trace, and the first signal trace passes through a portion of the board body that is located at a bottom side of the chip installation region.

### CROSS-REFERENCE TO RELATED APPLICATIONS

This application is a continuation of International Application No. PCT/CN2024/102144, filed on Jun. 27, 2024, which claims priority to Chinese Patent Application No. 202310834211.4, filed with the China National Intellectual Property Administration on Jul. 7, 2023 and entitled “CIRCUIT BOARD AND ELECTRONIC DEVICE”, which is incorporated herein by reference in its entirety.

### TECHNICAL FIELD

This application relates to the field of electronic technology, and in particular, to a circuit board and an electronic device.

### BACKGROUND

Currently, as the capacity of the switch chip is increasingly large, the rate of the serializer/deserializer (SERDES) is increasingly high, evolving from an early 10 Gbps to the current 112 Gbps. A higher signal rate leads to a greater signal loss per unit length on a transmission line.

With the standard of a direct-drive system as an example, the trace loss on a printed circuit board (PCB) is limited to 7 dB, which translates to a trace length of approximately 9 inches. Moreover, to meet the standard requirements, a PCB of the current M8 level (the highest level) is required.

### SUMMARY

An exemplary embodiment of this application discloses a circuit board and an electronic device.

According to a first aspect, a circuit board is provided. The circuit board includes a board body, where a surface of the board body has a chip installation region and a signal connector installation region arranged along a first direction; an end of the chip installation region away from the signal connector installation region has a first signal pin region, and in the chip installation region, the first signal pin region is the farthest from the signal connector installation region; and pins of the first signal pin region are in signal connection with corresponding pins of the signal connector installation region through a first signal trace, and the first signal trace passes through a portion of the board body that is located at a bottom side of the chip installation region. This can prevent the first signal trace from routing around a portion of the board body at a periphery of the chip installation region; and a space at the bottom side of the chip installation region is directly used as a channel for the first signal trace, so that a length of the first signal trace can be significantly shortened, thereby reducing loss.

In one embodiment, at least one end of the chip installation region in a second direction has a second signal pin region, a power pin region is provided on a side of the second signal pin region away from a corresponding side edge of the chip installation region, the first signal trace passes through a portion of the board body that is located at a bottom side of the second signal pin region, and the second direction is perpendicular to the first direction.

In one embodiment, the board body includes a first board layer and a second board layer that are stacked, and the chip installation region and the signal connector installation region are located on a surface of the first board layer facing away from the second board layer; each second signal pin region includes a first sub-region, pins of the first sub-region are in signal connection with corresponding pins of the signal connector installation region through a first sub-signal trace, and the first sub-signal trace passes through a portion of the first board layer that is located at a bottom side of the first sub-region; and the first signal trace passes through a portion of the second board layer that is located at a bottom side of the first sub-region.

In one embodiment, each second signal pin region further includes a second sub-region, where in each second signal pin region, the second sub-region is located between the first sub-region and a corresponding side edge of the chip installation region; pins of each second sub-region are in signal connection with corresponding pins of the signal connector installation region through a second sub-signal trace, and the second sub-signal trace fans out from the second sub-region in a direction away from the corresponding first sub-region; and along a direction approaching the signal connector installation region, the second sub-signal traces corresponding to the pins of the second sub-region are gradually arranged toward an inner side, the inner side referring to a side of the second sub-region in a direction toward the corresponding first sub-region.

In one embodiment, the first signal trace and the first sub-signal trace are both located on an inner side of any one of the second sub-signal traces of the corresponding second sub-region.

In one embodiment, the second sub-signal trace passes through both the first board layer and the second board layer; or the second sub-signal trace passes through the second board layer.

In one embodiment, an end of the chip installation region close to the signal connector installation region has a third signal pin region; and pins of the third signal pin region are in signal connection with corresponding pins of the signal connector installation region through a second signal trace, and the second signal trace passes through the board body and fans out toward the signal connector installation region along the first direction.

In one embodiment, the first board layer includes first dielectric layers and first metal layers alternately arranged in sequence, the first board layer has a first metal via hole running through the first board layer along a thickness direction and connected to the first metal layers, and the first metal layers and the first metal via hole are used to form the first sub-signal trace; and the second board layer includes second dielectric layers and second metal layers alternately arranged in sequence, the second board layer has a second metal via hole running through the second board layer along a thickness direction and connected to the second metal layers, and the second metal layers and the second metal via hole are used to form the first signal trace.

In one embodiment, the first board layer and the second board layer are individually formed single boards and are laminated to form the board body.

According to a second aspect, an electronic device is provided. The electronic device includes a chip, a signal connector, and the circuit board according to any one of the above technical solutions, where the chip is installed in the chip installation region and is in signal connection with pins of the chip installation region, and the signal connector is installed in the signal connector installation region and is in signal connection with pins of the signal connector installation region.

### BRIEF DESCRIPTION OF DRAWINGS

To describe the technical solutions of the embodiments of this application more clearly, the following briefly describes the accompanying drawings required for describing the embodiments of this application. Apparently, the accompanying drawings in the following descriptions show merely some embodiments of this application, and persons of ordinary skill in the art may still derive other accompanying drawings from these accompanying drawings without creative efforts.

FIG. 1 is a schematic structural diagram of fitting of a circuit board, a chip, and an optical port device in a related technical solution;

FIG. 2 is a schematic structural diagram of fitting of a circuit board and a signal connector according to an embodiment of this application;

FIG. 3 is a schematic diagram of a chip installation region in FIG. 2;

FIG. 4 is a cross-sectional view at position A-A of the circuit board shown in FIG. 3;

FIG. 5 is a partial longitudinal sectional view of the circuit board shown in FIG. 2; and

FIG. 6 is a schematic structural diagram of a first board layer of the circuit board shown in FIG. 2.

### DETAILED DESCRIPTION OF EMBODIMENTS

The following clearly and thoroughly describes the technical solutions in the embodiments of this application with reference to the accompanying drawings in the embodiments of this application. Apparently, the described embodiments are only some rather than all embodiments of this application. All other embodiments obtained by persons of ordinary skill in the art based on the embodiments of this application without creative efforts shall fall within the protection scope of this application.

In this application, the ordinal terms such as “first”, “second”, and the like used to modify elements do not indicate any priority, precedence, or order of one element with respect to another element, or the temporal sequence of actions in a method. Unless otherwise specified, such ordinal terms are used merely as labels to distinguish one element having a particular name from another element having the same name (except for the ordinal terms).

In a case that the terms “include”, “have”, and “comprise” as described in this application are used, unless explicit limiting terms such as “only” and “consisting of” are used, another component may also be added. Unless stated to the contrary, the terms in the singular form may include the plural form and should not be construed as being limited to a single quantity.

In the related art, how to shorten the length of a high-speed trace on a printed circuit board (PCB) and reduce total loss is a critical aspect of signal integrity (SI) design.

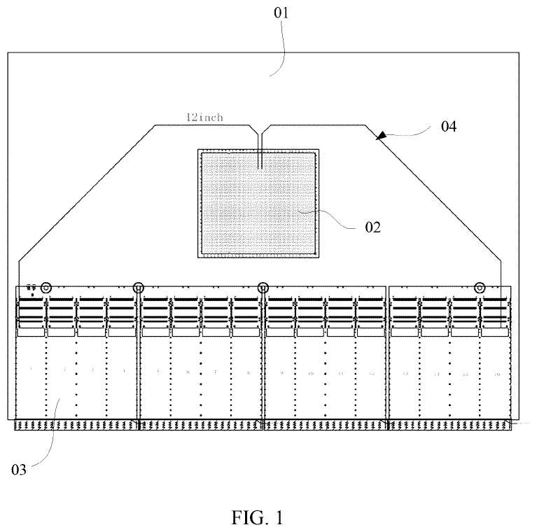

Referring to FIG. 1, with a PCB design of a switch device as an example, a top-level switch chip 02 in the current industry is used in the related art. A total of 512 pairs of high-speed SERDES are arranged on a surface of a PCB 01 and distributed around a peripheral portion of the entire chip 02. Power pins of the chip 02 are arranged in a middle region of the chip. The chip 02 is placed at a middle position of the PCB 01, and a lower side edge of the PCB 01 is entirely provided with optical port devices 03. High-speed traces 04 in a top region of the chip 02 (a region away from the optical port devices 03) and optical port devices 03 in a front row are interconnected. To avoid crossing between the traces 04, the top region can only be connected to optical port devices 03 at both ends, such that lengths of the traces 04 are large and are approximately 12 inches, failing to meet the standard requirements.

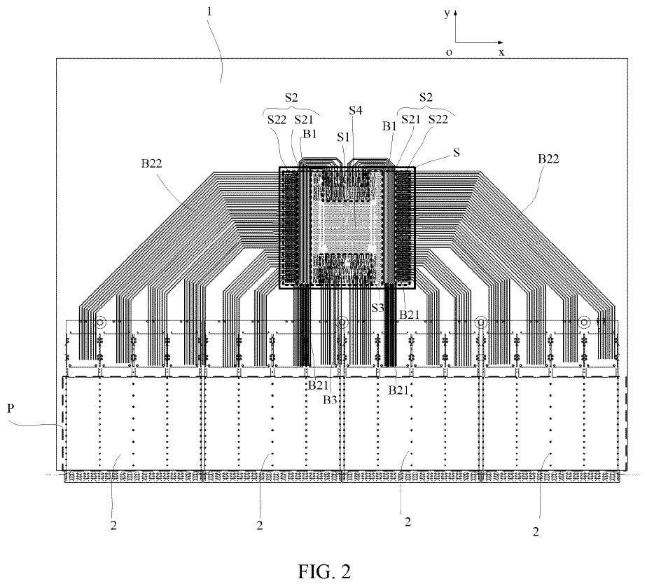

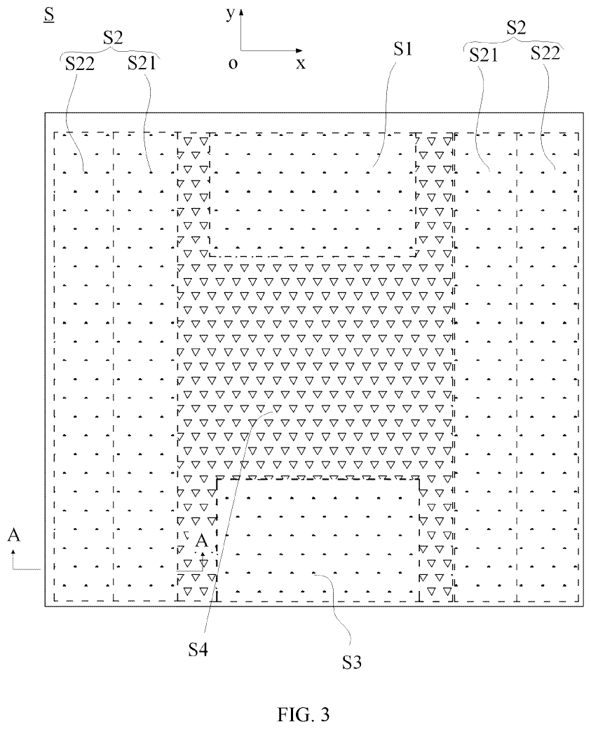

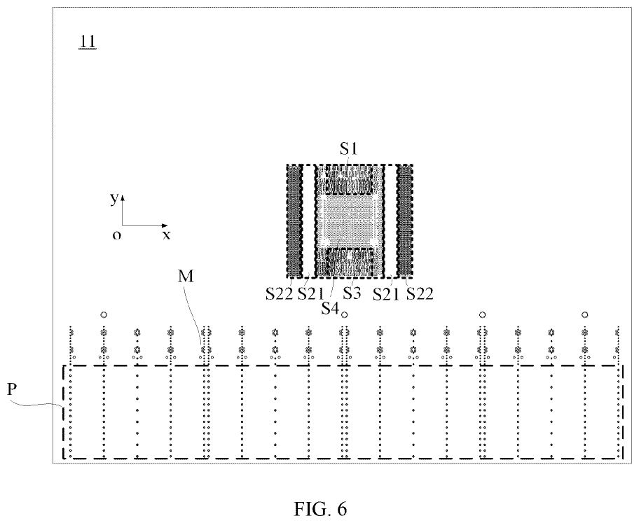

Referring to FIG. 2 and FIG. 3, a circuit board provided by an embodiment of this application includes but is not limited to a PCB (printed circuit board). The circuit board includes a board body 1, where a surface of the board body 1 has a chip installation region S and a signal connector installation region P arranged along a first direction (referring to a y-axis direction). The chip installation region S refers to an entire projection region of the chip in contact with the PCB. The region P refers to a region for placing optical modules (or devices including but not limited to the optical modules). A fan-out trace from the chip needs to be routed to the region P for connection with other devices. An end of the chip installation region S away from the signal connector installation region P has a first signal pin region S1, where in the chip installation region S, the first signal pin region S1 is farther from the signal connector installation region P than the chip; and pins of the first signal pin region S1 are in signal connection with corresponding pins of the signal connector installation region P (positions of the pins may refer to positions of metal via holes M at a bottom in FIG. 6) through a first signal trace B1. The first signal trace B1, along an extension direction of the board body between the first signal pin region S1 and the signal connector installation region P, passes through a portion of the board body 1 that is located at a bottom side of the chip installation region S until the signal connector installation region P is connected to the corresponding pins. This can prevent the first signal trace B1 from routing around a portion of the board body 1 at a periphery of the chip installation region S; and a space at the bottom side of the chip installation region S is directly used as a channel for the first signal trace B1, so that a length of the first signal trace B1 can be significantly shortened, thereby reducing loss. The pins may be SERDES. The circuit board provided by the exemplary embodiment of this application is configured to shorten the length of the trace without increasing costs, thereby reducing signal loss.

In one specific embodiment, at least one end of the chip installation region S in a second direction (referring to an x-axis direction) has a second signal pin region S2. In FIG. 2 and FIG. 3, both ends of the chip installation region S each have one second signal pin region S2. The second signal pin region S2 extends along an extension direction of a corresponding side edge of the chip installation region S to fully utilize the space increased outside the side edges of the chip installation region S (for example, two side edges of the chip installation region in the x-axis direction) to increase the number of fan-out traces. A power pin region S4 is provided on a side of the second signal pin region S2 away from a corresponding side edge of the chip installation region S. The first signal trace B1 passes through a portion of the board body 1 that is located at a bottom side of the second signal pin region S2 without interfering with devices such as capacitors in the power pin region S4, thereby improving signal transmission performance. Additionally, increasing the space outside the side edges of the chip installation region S for routing avoids an increase in a thickness or the number of layers of the board body 1. In this embodiment, the second direction (referring to the x-axis direction) is perpendicular to the first direction (referring to the y-axis direction).

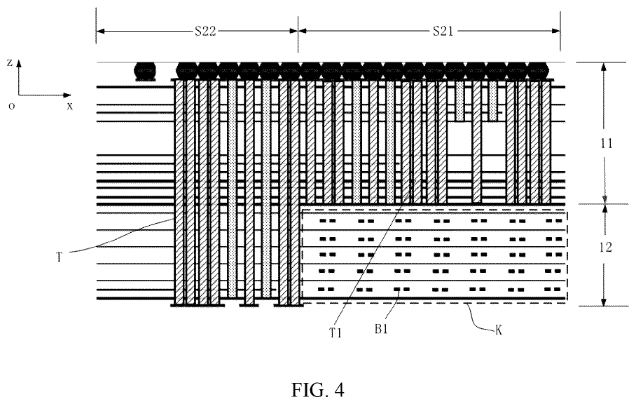

In one specific embodiment, referring to FIG. 4 to FIG. 6, the board body 1 includes a first board layer 11 and a second board layer 12 that are stacked, and the chip installation region S and the signal connector installation region P are located on a surface of the first board layer 11 facing away from the second board layer 12; each second signal pin region S2 includes a first sub-region S21, pins of the first sub-region S21 are in signal connection with corresponding pins of the signal connector installation region P through a first sub-signal trace B21 (referring to FIG. 2), and the first sub-signal trace B21 passes through a portion of the first board layer 11 that is located at a bottom side of the first sub-region S21; and the first signal trace B1 passes through a portion of the second board layer 12 that is located at a bottom side of the first sub-region S21. Thus, to form the first sub-signal trace B21 for routing the pins of the first sub-region S21, a via hole (for example, a metal via hole, where the form of the metal via hole may refer to a first metal via hole T1, a second metal via hole T2, and a through-hole T described later) needs to be formed along a thickness direction (referring to a z-axis direction).

If the first sub-signal trace B21 passes through the second board layer 12, a metal via hole corresponding to the first sub-signal trace B21 passes through a portion of the first board layer 11 corresponding to the first sub-region S21, making it impossible to route traces in the corresponding portion of the first board layer 11, and making it impossible for the first signal trace B1 to pass through the corresponding portion of the first board layer 11. In the embodiment shown in FIG. 4, the first sub-signal trace B21 is arranged in the first board layer 11 corresponding to the first sub-region S21, a metal via hole corresponding to the first sub-signal trace B21 only passes through the first board layer 11 without entering a portion of the second board layer 12 corresponding to the first sub-region S21, thereby avoiding interference with traces in the portion of the second board layer 12, that is, a clear space retained in the portion of the second board layer 12 corresponding to the first sub-region S21 can be used to form a routing channel K for the first signal trace B1. Meanwhile, FIG. 6 shows formation of a metal via hole in the first board layer 11, where no metal via hole obstructs a position of the first board layer 11 corresponding to the first sub-region S21, and a region of this position correspondingly forms the routing channel K. Metal layers and dielectric layers may be alternately arranged in the routing channel K. The metal via hole and the metal layers are used to form the first signal trace B1.

Referring to FIG. 2, the first signal trace B1 first extends out of the chip installation region S in a direction away from the signal connector installation region P and then splits into two paths along the second direction (referring to the x-axis direction) toward the first sub-regions S21 on both sides. After reaching tops of the first sub-regions S21, the first signal trace B1 extends along the first direction (referring to the y-axis direction) through the routing channel K toward the signal connector installation region P. The first sub-signal trace B21 extends directly along the first direction (referring to the y-axis direction) toward the signal connector installation region P. Since the first signal trace B1 and the first sub-signal trace B21 are distributed in different board layers, the first signal trace B1 and the first sub-signal trace B21 do not interfere or cross each other and may be in signal connection with different signal connectors 2 in the signal connector installation region P, respectively.

In one specific embodiment, each second signal pin region S2 further includes a second sub-region S22, where in each second signal pin region S2, the second sub-region S22 is located between the first sub-region S21 and a corresponding side edge of the chip installation region S, that is, the second sub-region S22 is located outside the corresponding first sub-region S21. Pins of each second sub-region S22 are in signal connection with corresponding pins of the signal connector installation region P through a second sub-signal trace B22. The second sub-signal trace B22 extends out of the chip installation region S from the second sub-region S22 in a direction away from the corresponding first sub-region S21, and the second sub-signal trace B22 gradually approaches the signal connector installation region P during fanning out. Along a direction approaching the signal connector installation region P, the second sub-signal traces B22 corresponding to the pins of the second sub-region S22 are gradually arranged toward an inner side, the inner side referring to a side of the second sub-region S22 in a direction toward the corresponding first sub-region S21 in the same second signal pin region S2, thus preventing crossing between different signal traces so as not to increase a thickness or the number of layers of the circuit board. As shown in FIG. 2, when the pins in the second sub-region S22 are farther from the signal connector installation region P, pins in the signal connector installation region P corresponding to the pins are farther from the chip installation region S in the second direction (referring to the x-axis direction), making it less likely for different second sub-signal traces B22 to cross each other. Since the second sub-region S22 is located outside the corresponding first sub-region S21, the second sub-region S22 can fan out in a direction away from the corresponding first sub-region S21. Conversely, the second sub-region S22 is located inside the corresponding first sub-region S21, the second sub-signal trace B22 is blocked by the first signal trace B1 and the first sub-signal trace B21 and cannot fan out.

In one specific embodiment, the first signal trace B1 and the first sub-signal trace B21 are both located on an inner side of any one of the second sub-signal traces B22 of the corresponding second sub-region S22, where the definition of “inner side” refers to the foregoing description, thereby preventing the second sub-signal trace B22 from crossing the first signal trace B1 and the first sub-signal trace B21.

In one specific embodiment, the second sub-signal trace B22 passes through both the first board layer 11 and the second board layer 12 to increase the number of second sub-signal traces B22 fanning out from the second sub-region S22, which is conducive to increasing the number of pins and improving performance; or the second sub-signal trace B22 passes through only the second board layer 12, which helps the second sub-signal trace B22 to avoid the first sub-signal trace B21 in the first board layer 11, thereby providing fanning-out space for the first sub-signal trace B21.

In one specific embodiment, an end of the chip installation region S close to the signal connector installation region P has a third signal pin region S3. Pins of the third signal pin region S3 are in signal connection with corresponding pins of the signal connector installation region P through a second signal trace B3. The second signal trace B3 passes through the board body 1 and fans out toward the signal connector installation region P along the first direction (referring to the y-axis direction). The second signal trace B3 has the shortest trace length and is less likely to interfere with other signal traces.

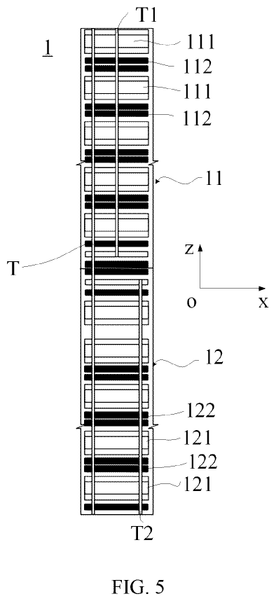

In one specific embodiment, referring to FIG. 5, the first board layer 11 includes first dielectric layers 112 and first metal layers 111 alternately arranged in sequence. The first board layer 11 is provided with a first metal via hole T1 running through the first board layer 11 along a thickness direction (referring to a z-axis direction) and connected to the first metal layers 111. The first metal layers 111 and the first metal via hole T1 are used to form the first sub-signal trace B21, facilitating processing and stable transmission for signals of the pins of the first sub-region S21. The second board layer 12 includes second dielectric layers 122 and second metal layers 121 alternately arranged in sequence. The second board layer 12 is provided with a second metal via hole T2 running through the second board layer 12 along the thickness direction (referring to the z-axis direction) and connected to the second metal layers 121. The second metal layers 121 and the second metal via hole T2 are used to form the first signal trace B1, facilitating processing and stable transmission for signals of pins of the first signal pin region S1. The first metal via hole T1 and the second metal via hole T2 can respectively form a metal via hole running through the first board layer 11 and a metal via hole running through the second board layer 12. For example, such metal via holes can be used to form the first sub-signal trace B21 and the first signal trace B1, respectively. When the second sub-signal trace B22 that passes through both the first board layer 11 and the second board layer 12 needs to be formed, a through-hole T running through the entire board body 1 can be formed as a metal via hole.

In one specific embodiment, the first board layer 11 and the second board layer 12 are individually formed single boards and are laminated to form the board body 1. The first board layer 11 serves as an upper N-layer board, and the second board layer 12 serves as a lower N-layer board. The PCB adopts an N-layer+N-layer design process. In this process, the PCB is vertically divided into two parts, where an upper half part is called the upper N-layer board, and a lower half part is called the lower N-layer board. Due to technical limitations, when metal via holes are formed, the metal via holes can only fully run through the board. In some cases (for example, a case where the first sub-signal trace B21 is formed), only the first metal via hole T1 needs to be formed at a corresponding position of the first board layer 11, so only the first metal via hole T1 running through the first board layer 11 needs to be formed in the first board layer 11 serving as a single board, while the second metal via hole T2 does not need to be formed at a corresponding position of the second board layer 12. This is conducive to saving the routing space in the second board layer 12. Similarly, this is also conducive to saving the routing space in the first board layer 11. After the first board layer 11 and the second board layer 12 are laminated together, a through-hole T running through the entire board body 1 is drilled.

The upper N-layer board and the lower N-layer board are used to reuse the wiring space in a region with dense via holes of the chip. In some specific embodiments, tests show that the length of the first signal trace B1 of the first signal pin region S1 can be shortened by approximately 30% compared to the technical solution corresponding to FIG. 1. The wiring space is fully used, and traces can extend from all four sides, so that the issue of crossing of the traces can be addressed.

With unchanged loss, this solution can lower the board material by one grade, and in some specific embodiments, tests show that the overall cost of the PCB can be reduced by approximately 20%. Moreover, the solution provided by the above embodiments can simplify the architecture and meet the requirements of a pure PCB solution for direct drive.

Based on the same inventive concept, an embodiment of this application further provides an electronic device. The electronic device may be a switch, a router, or a server. The electronic device includes a chip, a signal connector 2, and the circuit board provided by the above embodiments. The chip is installed in the chip installation region S and is in signal connection with pins of the chip installation region S, and the signal connector 2 is installed in the signal connector installation region P and is in signal connection with pins of the signal connector installation region P. The effects can refer to the circuit board described above. The signal connector 2 may be an optical port device such as an optical module.

Apparently, persons skilled in the art can make various modifications and variations to this application without departing from the spirit and scope of this application. Thus, if these modifications and variations of this application fall within the scope of the claims of this application and their equivalent technologies, this application is also intended to include these modifications and variations.

What is claimed is:

1. A circuit board, comprising:
a board body, wherein a surface of the board body has a chip installation region and a signal connector installation region arranged along a first direction, and an end of the chip installation region away from the signal connector installation region has a first signal pin region; and
a first signal trace, wherein the first signal trace is configured to enable signal connection between pins of the first signal pin region and corresponding pins of the signal connector installation region, and the first signal trace passes through a portion of the board body that is located at a bottom side of the chip installation region.

2. The circuit board according to claim 1, wherein at least one end of the chip installation region in a second direction has a second signal pin region, the first signal trace passes through a portion of the board body that is located at a bottom side of the second signal pin region, and the second direction is perpendicular to the first direction.

3. The circuit board according to claim 2, wherein a power pin region is provided on a side of the second signal pin region away from a corresponding side edge of the chip installation region.

4. The circuit board according to claim 2, wherein the board body comprises a first board layer and a second board layer that are stacked, and the chip installation region and the signal connector installation region are located on a surface of the first board layer facing away from the second board layer;
the second signal pin region comprises a first sub-region, pins of the first sub-region are in signal connection with corresponding pins of the signal connector installation region through a first sub-signal trace, and the first sub-signal trace passes through a portion of the first board layer that is located at a bottom side of the first sub-region; and
the first signal trace passes through a portion of the second board layer that is located at the bottom side of the first sub-region.

5. The circuit board according to claim 4, wherein the second signal pin region further comprises a second sub-region, and in the second signal pin region, the second sub-region is located between the first sub-region and a corresponding side edge of the chip installation region; and
each of a plurality of pins of the second sub-region is in signal connection with a corresponding pin of the signal connector installation region through a respective second sub-signal trace of a plurality of second sub-signal traces, and the plurality of second sub-signal traces fan out from the second sub-region in a direction away from the corresponding first sub-region.

6. The circuit board according to claim 5, wherein
along a direction approaching the signal connector installation region, the second sub-signal traces corresponding to the pins of the second sub-region are arranged along an inner side, the inner side referring to a side of the second sub-region in a direction toward the corresponding first sub-region.

7. The circuit board according to claim 5, wherein the first signal trace and the first sub-signal trace are both located on a side of the second sub-signal trace of the second sub-region where the first signal pin region is located.

8. The circuit board according to claim 5, wherein the second sub-signal trace passes through both the first board layer and the second board layer; or
the second sub-signal trace passes through the second board layer.

9. The circuit board according to claim 1, wherein an end of the chip installation region close to the signal connector installation region has a third signal pin region; and
pins of the third signal pin region are in signal connection with corresponding pins of the signal connector installation region through a second signal trace, and the second signal trace passes through the board body and fans out toward the signal connector installation region along the first direction.

10. The circuit board according to claim 4, wherein the first board layer comprises first dielectric layers and first metal layers alternately arranged in sequence, the first board layer has a first metal via hole running through the first board layer along a thickness direction and connected to the first metal layers, and the first metal layers and the first metal via hole are used to form the first sub-signal trace.

11. The circuit board according to claim 10, wherein
the second board layer comprises second dielectric layers and second metal layers alternately arranged in sequence, the second board layer has a second metal via hole running through the second board layer along a thickness direction and connected to the second metal layers, and the second metal layers and the second metal via hole are used to form the first signal trace.

12. The circuit board according to claim 4, wherein the first board layer and the second board layer are individually formed single boards, and the board body is formed by laminating the first board layer and the second board layer together.

13. An electronic device, comprising: a chip, a signal connector, and the circuit board according to claim 1, wherein the chip is installed in the chip installation region and is in signal connection with pins of the chip installation region, and the signal connector is installed in the signal connector installation region and is in signal connection with pins of the signal connector installation region.
